(19) United States
(12) Patent Application Publication
(10) Pub. No.: US 2026/0031309 A1
(43) Pub. Date: Jan. 29, 2026

(54) METHODS AND SYSTEMS FOR COATED COMPONENTS OF A PLASMA PROCESSING SYSTEM

(71) Applicants: Beijing E-Town Semiconductor Technology Co., Ltd., Beijing (CN); Mattson Technology, Inc., Fremont, CA (US)

(72) Inventors: Songjae Lee, San Jose, CA (US); Eran Newman, Los Altos, CA (US); Schubert Chu, San Francisco, CA (US); Qi Zhang, San Jose, CA (US)

(21) Appl. No.: 19/283,743

(22) Filed: Jul. 29, 2025

Related U.S. Application Data
(60) Provisional application No. 63/676,656, filed on Jul. 29, 2024.

(51) Int. Cl. H01J 37/32; H01L 21/687

(52) U.S. Cl. CPC H01J 37/32724; H01J 37/32091; H01J 37/3244; H01L 21/68757

(57) ABSTRACT

Systems and methods for plasma processing of a semiconductor workpiece are provided. In one example, a plasma processing system includes a plasma chamber. The plasma processing system includes an inductive coil disposed about the plasma chamber. The plasma processing system includes a processing chamber downstream of the plasma chamber. The plasma processing system includes a workpiece support in the processing chamber. The plasma processing system includes a component with a coating in the processing chamber, the plasma chamber, or between the processing chamber and the plasma chamber.

### PRIORITY CLAIM

The present application claims the benefit of priority of U.S. Provisional Application Ser. No. 63/676,656, titled “Methods and Systems for Electroplated Components of a Plasma Processing Chamber,” filed on Jul. 29, 2024, which is incorporated herein by reference.

### FIELD

The present disclosure relates generally to processing systems and methods for processing workpieces, such as semiconductor workpieces.

### BACKGROUND

Plasma processing is widely used in the semiconductor industry for deposition, etching, resist removal, and related processing of semiconductor wafers and other workpieces. Plasma sources (e.g., microwave, ECR, inductive, etc.) are often used for plasma processing to produce high density plasma and reactive species for processing workpieces. Plasma strip tools can be used for strip processes, such as photoresist removal. Plasma strip tools can include a plasma chamber where plasma is generated and a separate processing chamber where the workpiece is processed. The processing chamber can be “downstream” of the plasma chamber such that there is no direct exposure of the workpiece to the plasma. A separation grid can be used to separate the processing chamber from the plasma chamber. The separation grid can be transparent to neutral species but not transparent to charged particles from the plasma. The separation grid can include a sheet of material with holes.

### SUMMARY

Aspects and advantages of embodiments of the present disclosure will be set forth in part in the following description, or can be learned from the description, or can be learned through practice of the embodiments.

One example aspect of the present disclosure is directed to a plasma processing system. The plasma processing system includes a plasma chamber. The plasma processing system includes an inductive coil disposed about the plasma chamber. The plasma processing system includes a processing chamber downstream of the plasma chamber. The plasma processing system includes a workpiece support in the processing chamber. The plasma processing system includes a component with a coating in the processing chamber, the plasma chamber, or between the processing chamber and the plasma chamber.

Another example aspect of the present disclosure is directed to a method for providing a coating to a component for use in a plasma processing system. The method includes implementing a deposition process to a component of a plasma processing system to provide a coating on a surface of the component.

Another example aspect of the present disclosure is directed to a plasma processing system. The plasma processing system includes a plasma chamber. The plasma processing system includes an inductive coil disposed about the plasma chamber. The plasma processing system includes a processing chamber downstream of the plasma chamber. The plasma processing system includes a workpiece support in the processing chamber. The plasma processing system includes a thermal structure. The plasma processing system includes a coating disposed on the thermal structure.

Another example aspect of the present disclosure is directed to a component for a plasma processing chamber. The component includes a body comprising a first material; and a coating on at least a surface of the body, the coating comprising a material different from the first material, wherein the coating is configured to be exposed to a plasma during processing of a workpiece.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts an example plasma processing system according to example embodiments of the present disclosure.

FIG. 2 depicts an overview of an example method for providing a coating, such as an electroplated coating, to a component for use in a plasma processing system according to example embodiments of the present disclosure.

FIG. 3 depicts a coated component after undergoing a coating process according to example aspects of the present disclosure.

FIG. 4A depicts a workpiece support that includes a thermal structure according to example embodiments of the present disclosure.

FIG. 4B depicts a workpiece support that includes a thermal structure according to example embodiments of the present disclosure.

FIG. 4C depicts a workpiece support according to example embodiments of the present disclosure.

FIG. 4D depicts a workpiece support that includes a thermal structure according to example embodiments of the present disclosure.

FIG. 5 depicts an example coating system according to example embodiments of the present disclosure.

FIG. 6 depicts a flowchart diagram of an example method according to example embodiments of the present disclosure.

FIG. 7 depicts an example plasma processing system according to example embodiments of the present disclosure.

FIG. 8 depicts an example plasma processing system according to example embodiments of the present disclosure.

FIG. 9 depicts an example plasma processing system according to example embodiments of the present disclosure.

FIG. 10 depicts an example plasma processing system according to example embodiments of the present disclosure.

FIG. 11 depicts an example plasma processing system according to example embodiments of the present disclosure.

FIG. 12 depicts an example plasma processing system according to example embodiments of the present disclosure.

FIG. 13 depicts an example plasma processing system according to example embodiments of the present disclosure.

FIG. 14 depicts an example plasma processing system according to example embodiments of the present disclosure.

Repeat use of reference characters in the present specification and drawings is intended to represent the same and/or analogous features or elements of the present invention.

### DETAILED DESCRIPTION

Reference will now be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Aspects of the present disclosure are directed to processing systems and methods for processing workpieces, such as semiconductor workpieces. For instance, one example aspect of the present disclosure is directed to a plasma processing system. The system includes a processing chamber. The system includes a workpiece support operable to support a workpiece in the processing chamber. In some examples, the workpiece support may include a thermal structure, or other thermal system operable to heat or cool a workpiece during a plasma-based process. The system may include a plasma chamber that is separated from the processing chamber by a separation grid. The system may include one or more induction coils about the plasma chamber. The induction coil may be operable to generate a plasma from a process gas in the plasma chamber. The system may include a separation grid positioned between the processing chamber and the plasma chamber. The separation grid may allow neutral species generated in the plasma to flow through the separation grid to the processing chamber for exposure to the workpiece, while filtering charged species (e.g., ions) generated in the plasma.

One example aspect of the present disclosure is directed to a component (e.g., the separation grid, the thermal structure, the showerhead, the gas injection insert, etc.) for use in a plasma processing system. The component for use in a plasma processing system may include an alloy having a bulk material element (e.g., aluminum) with additional alloying elements (e.g., iron, copper, silicon, etc.). When employed in a plasma processing chamber, the presence of alloying elements can lead to process abnormalities as alloying elements interact with species of the plasma. This is especially apparent when a plasma processing system employs a hydrogen plasma, as hydrogen interactions with the alloying elements may create impurities in the plasma chemistry. This can alter the plasma-based process and create non-uniformities of process conditions at the workpiece.

According to example aspects of the present disclosure, the impacts of the interaction of plasma species with alloying elements of the component in the plasma processing system (e.g., the separation grid, the thermal structure, etc.) may be mitigated by providing a protective barrier to the surface of the component. In some examples, the protective barrier may be applied to the surface of the component through an electrochemical process (e.g., electroplating) or other suitable process, such as physical vapor deposition (PVD) or other suitable deposition process. In some examples, the protective barrier may include the same material as the bulk material element of the alloy (e.g., the bulk material element matrix that hosts the alloying elements).

Certain components of a plasma processing system may need to have high thermal conductivity. For instance, the thermal structure (e.g., cooling channels, heating elements, etc.) in a workpiece support structure may be formed from a material with high thermal conductivity. Certain materials are known to provide high thermal conductivity but are difficult to incorporate into plasma processing systems. This may be due to undesired interactions of the material of the component with plasma chemistry employed by a plasma processing system. For instance, copper has high thermal conductivity but may create negative interactions with certain plasma chemistries. Aspects of the present disclosure may provide a protective surface (e.g., a coating) to the material with high thermal conductivity (e.g., copper) so that the material can be utilized in a plasma processing system with reduced effects on the plasma chemistry.

Accordingly, aspects of the present disclosure are directed toward a plasma processing system having a component with a coating, such as a deposited coating, such as an electroplated coating or other coating (e.g., PVD defined coating). In some examples, the coating of the coated component may then be anodized to produce a coated component with an anodized coating (e.g., an anodized electroplated coating). In some examples, the coating may be an electroplated coating.

Aspects of the present disclosure are discussed with reference to electroplated coatings for purposes of illustration and discussion. Those of ordinary skill in the art, using the disclosures provided herein, will understand that the coating may be provided on a component using any suitable process, such as a deposition process, such as physical vapor deposition, chemical vapor deposition, etc.

In some examples, the plasma processing system includes a plasma chamber, an inductive coil disposed about the plasma chamber, a processing chamber downstream of the plasma chamber, and a workpiece support in the processing chamber that is configured to at least partially heat or cool a semiconductor workpiece through a thermal structure. In some examples, the thermal structure includes a coating (e.g., an electroplated coating, such as an anodized electroplated coating).

In some examples, the component with the coating (e.g., electroplated coating, such as an anodized electroplated coating) is at least a part of a separation grid separating the plasma chamber from the processing chamber. In some examples, the component with the coating (e.g., electroplated coating, such as an anodized electroplated coating) is at least a part of the workpiece support, wherein the workpiece support is configured to at least partially heat or cool a semiconductor workpiece through the thermal structure. In some examples, the component with the coating (e.g., electroplated coating, such as an anodized electroplated coating) is at least a part of a showerhead used to deliver process gas within the plasma processing system. In some examples, the component with the coating (e.g., electroplated coating, such as an anodized electroplated coating) is at least a part of a gas injection insert. In some examples, the component with the coating is at least a part of a Faraday shield, a confinement ring, or a chamber wall in the plasma chamber, the processing chamber, or another chamber of the plasma processing system.

In some examples, the plasma processing system includes a first electrode and a second electrode, wherein at least one of the first electrode or the second electrode are biased to provide a capacitively coupled plasma source. In some examples, the component with the coating includes at least one of the first electrode or the second electrode.

In some examples, the component with the coating comprises an alloy. In some examples, the coating is a material that is the same as a bulk material element of the alloy. In some examples, the coating has a thickness in a range of about 2 microns to about 400 microns, such as in a range of about 5 microns to about 200 microns, such as about 10 microns to about 100 microns, such as about 10 microns, such as about 100 microns. In some examples, the component with the coating is anodized (e.g., an anodized electroplated coating). In some examples, the coating (e.g., an anodized electroplated coating) includes an aluminum coating. In some examples, the aluminum coating has a purity of at least about 90%, such as at least about 95%, such as at least about 97.5%, such as at least about 99.99%, such as in a range of about 90% to about 99.99%. In some examples, the aluminum coating is an anodized aluminum coating. In some examples, the anodized aluminum coating comprises an oxide layer at least about 2 micrometers to about 200 micrometers in thickness.

Some aspects of the present disclosure are directed toward a method to implement a deposition process (e.g., electroplating process, PVD process, CVD process, etc.) to a component of a plasma processing system that alters one or more characteristics of the component and produces a component with a coating (e.g., an electroplated coating, such as an anodized electroplated coating).

In some examples, the method may include providing the component with the coating to the plasma processing system. In some examples, the coating may be applied to the component. In some examples, the coating may be anodized to produce a coated component with an anodized coating (e.g., an anodized electroplated coating). In some examples, the coating is deposited using a solvent-based electrolyte. In some examples, the solvent-based electrolyte is an organic solvent.

In some examples, the coating disclosed herein is specifically configured to create a functionally superior plasma-facing surface that is independent of the properties of the underlying material of the component. In one aspect, the component is configured to present a chemically uniform surface to a plasma. An underlying material, such as a common aluminum alloy, is chemically non-uniform at a microscopic level due to the presence of various alloying elements (e.g., silicon, copper, iron) within the bulk aluminum matrix. These different elements have different erosion rates and reactivities when exposed to a process plasma, leading to process drift and non-uniformity. By applying a coating of a high-purity material (e.g., aluminum of at least 99.99% purity), a chemically homogenous surface is presented to the plasma, ensuring consistent interaction and stable process conditions. This functional surface is intentionally designed such that the coating has a surface reactivity to a process plasma that is lower than a surface reactivity of the underlying material of the component. For example, a high-purity aluminum coating, and especially an anodized aluminum oxide coating, is significantly more inert and less reactive than a standard aluminum alloy or other materials, thereby reducing erosion and extending the life of the component.

In another specific embodiment, the component may comprise a body made of copper, and the coating is configured to reduce interaction between a plasma and the copper of the component. Copper is a desirable material for certain components, such as a thermal structure (e.g., a heater or cooling plate), due to its excellent thermal conductivity. However, copper is highly reactive in many plasma environments and is a significant metallic contaminant in semiconductor manufacturing. Direct exposure of copper to a process plasma would lead to sputtering and severe contamination of the workpiece and chamber. According to aspects of the present disclosure, a non-reactive and plasma-compatible coating (e.g., high-purity aluminum or anodized aluminum) is disposed over the copper body. This coating acts as a robust physical and chemical barrier, effectively isolating the copper from the plasma. This configuration prevents the plasma species from interacting with, eroding, or sputtering the underlying copper, thus enabling the use of copper for its advantageous thermal properties without introducing its deleterious effects into the processing environment.

Aspects of the present disclosure provide numerous technical effects and benefits. For instance, providing a coating, such as an electroplated coating (e.g., an anodized electroplated coating) or a deposited coating (e.g., PVD defined coating), to a component may protect plasma process chemistry from anomalies while reducing material selection constraints of components of the plasma processing system. In one example, providing a thermal system that includes, at least in part, copper material with a coating that provides a protective barrier to the surface of the copper may allow copper-based thermal structures to be incorporated into the plasma processing system. In another example, providing a coating to an alloy that may contain alloying elements that negatively impact plasma process chemistry may reduce the interference of alloying elements with the plasma process chemistry. In some instances, providing a coating (e.g., an anodized electroplated coating) to a component may provide a protective barrier to the surface of the coated component, which may maintain the chemical composition and desired properties of the underlying material of the component and protect plasma process chemistry. In some examples, the coating (e.g., an anodized electroplated coating) may improve the quality of the workpiece or may increase the longevity of the component.

For example, providing a high-purity, dense, and uniform coating to a chamber component addresses several challenges in modern plasma processing. These benefits include, but are not limited to, a significant reduction in particle generation, improved plasma and process uniformity, an increase in component longevity and time between cleans, and a broader, more cost-effective selection of underlying materials for component fabrication. Ultimately, these improvements lead to lower workpiece defectivity, higher process repeatability, and increased equipment throughput.

For instance, by presenting a chemically homogenous and high-purity surface to the plasma, the coating may reduce process drift and non-uniformity that can arise from the preferential erosion or reaction of alloying elements in a base material. This can allow plasma chemistry to remain stable and uniform across the entire processing area, improving within-wafer process uniformity and wafer-to-wafer repeatability. Furthermore, the dense and smooth surface of the coating, particularly an electroplated or anodized electroplated coating, reduces defects and flaking and mitigates micro-arcing events, thereby reducing the generation of contaminant particles that can fall onto the workpiece. The enhanced resilience and lower reactivity of the coated surface also increase the operational lifetime of the component, extending the time between cleans and reducing equipment downtime. Additionally, the protective coating decouples the bulk material properties of the component from its plasma-facing surface properties, allowing for the use of less expensive or structurally superior substrate materials (e.g., lower-grade alloys) that would otherwise be unsuitable for direct plasma exposure.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece.

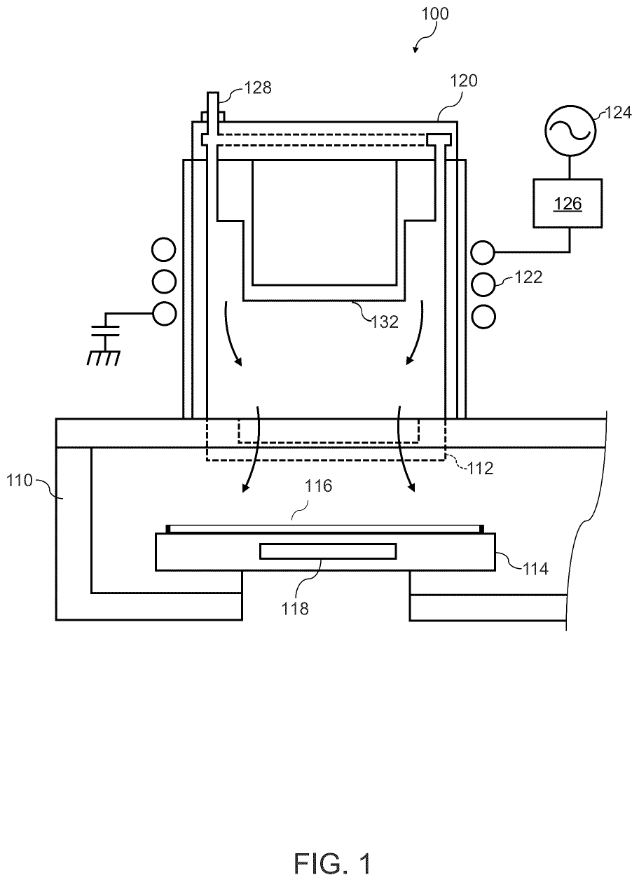

FIG. 1 depicts an example plasma processing system 100. The processing system 100 may include a processing chamber 110 and a plasma chamber 120 that may be separated from the processing chamber 110 by a separation grid 112. The processing chamber 110 may include a workpiece support 114 operable to hold a workpiece 116, such as a semiconductor workpiece. The workpiece support 114 may contain a thermal structure 118, such as cooling channels or heaters, that are operable to alter the temperature the workpiece 116 during a plasma processing operation. The thermal structure 118 may be located in other parts of the plasma processing system 100 without deviating from the scope of the present disclosure, such as in the separation grid 112, one or more walls of the processing chamber 110, in the plasma chamber 120, etc.

An induction coil 122 may be disposed about the plasma chamber 120. The induction coil 122 may be coupled to an RF power generator 124 through a suitable matching network 126. Reactant and carrier gases may be provided to the chamber interior from gas supply 128. When the induction coil 122 is energized with RF power from the RF power generator 134, a substantially inductive plasma may be induced in the plasma chamber 120.

The example plasma processing system 100 may include a gas injection insert 132. The gas injection insert may be removably inserted in the plasma chamber 120 interior or may be a fixed part within the plasma chamber 120. The gas injection insert 132 may feed or confine process gas into an active region of the plasma chamber 120.

A plasma may be generated in the plasma chamber 120 from process gases (e.g., reactant gas and carrier gases). The generated plasma species (e.g., ions and radicals) may then be provided from the plasma chamber 120 to the surface of workpiece 116, through holes provided in the separation grid 112. The separation grid 112 may be electrically grounded. The separation grid 112 may filter ions in the generated plasma species so that only neutral radicals pass from the plasma chamber 120 to the processing chamber 110 for exposure to the workpiece 116.

According to examples of the present disclosure, one or more components of the plasma processing system 100 may include a coating, such as an electroplated coating (e.g., an anodized electroplated coating) or PVD defined coating. For instance, one or more of the separation grid 112, the thermal structure 118, the gas injection insert 132, or other component may include a coating.

In some examples, the coating includes an aluminum coating with a purity of at least about 90%, such as at least about 95%, such as at least about 97.5%, such as at least about 99.99%, such as in a range of about 90% to about 99.99%. In some examples, the aluminum coating has a thickness that is at least about 10 microns, such as in a range of about 2 microns to about 400 microns, such as in a range of about 5 microns to about 200 microns, such as about 10 microns to about 100 microns, such as about 10 microns, such as about 100 microns. In some examples, the aluminum coating is anodized and includes an oxide layer at least about 2 micrometers to about 200 micrometers in thickness.

In some examples, the component, such as the separation grid 112, the gas injection insert 132, or other component may be formed from an alloy. An alloy, as used herein, refers to a material having a bulk material element (e.g., aluminum) and one or more alloying elements (e.g., iron, copper, silicon, etc.). In one example, the coating may be an aluminum coating, whereas the component (e.g., the separation grid 112, the gas injection insert 132, or other component) may be an aluminum alloy. In this example, the coating may be a material that is the same as a bulk material element of the component, such as the separation grid 112 or the gas injection insert 132.

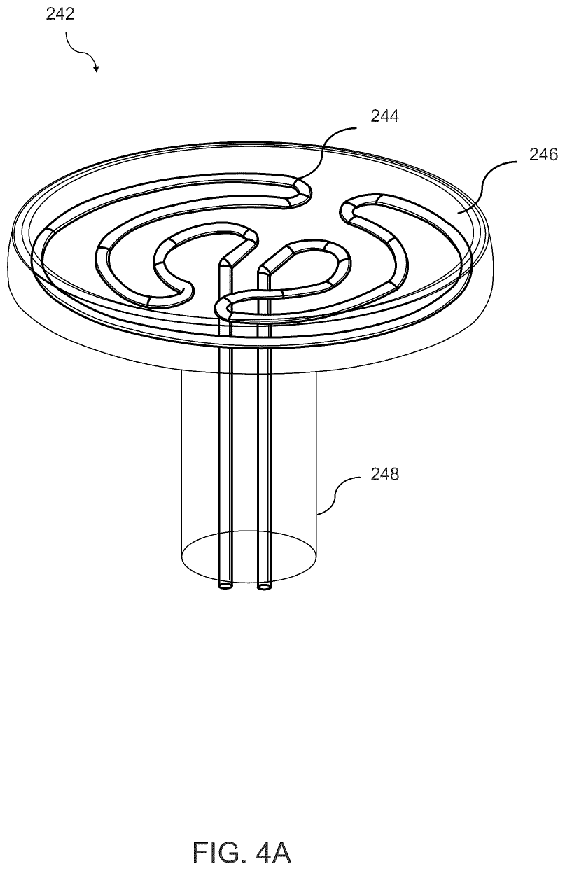

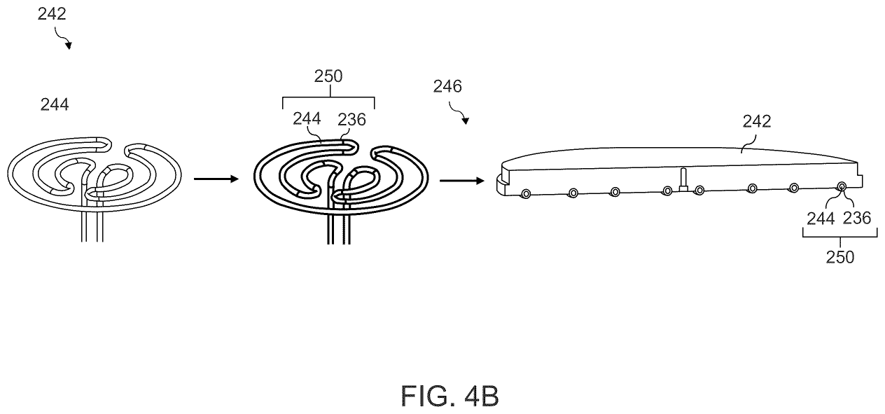

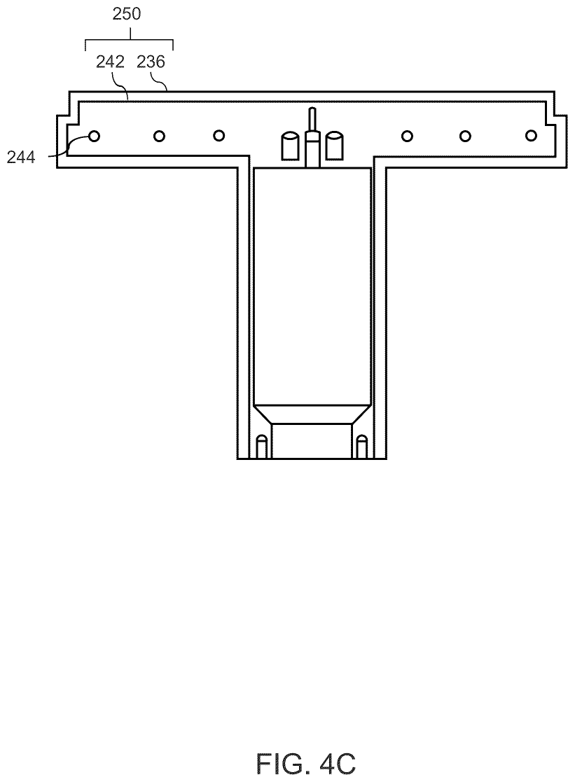

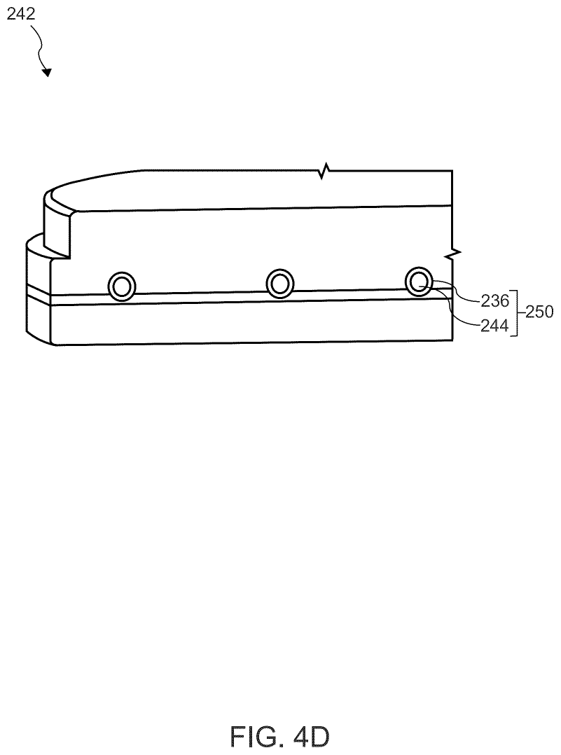

In some examples, as discussed below with reference to FIGS. 4A-4D, the thermal structure 118 may include a coating. In some examples, the coating may be a material that is different from the bulk material element of the component, such as the thermal structure 118. In some examples, the thermal structure 118 may include a copper structure, and the coating applied to the surface may be an aluminum coating. In this example, the coating largely includes a different material than the material of the thermal structure 118.

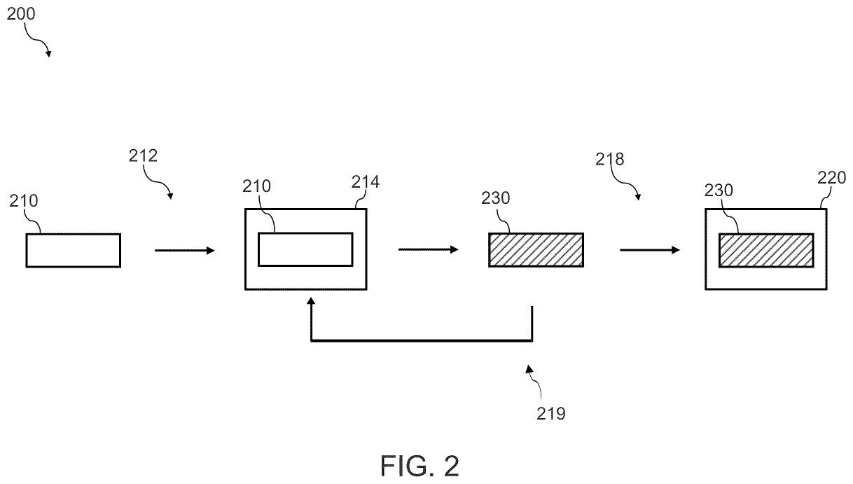

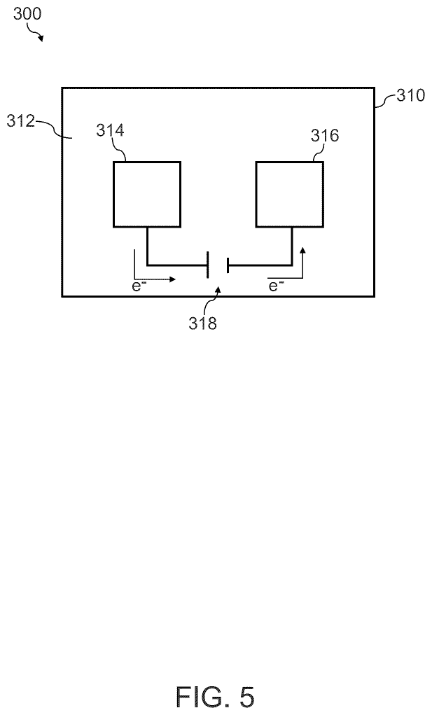

FIG. 2 depicts an overview of an example method 200 for providing a coating (e.g., an electroplated coating or PVD defined coating) to a component 210 for use in a plasma processing system according to aspects of the present disclosure. At 212, the method 200 includes providing the component 210 to a coating system 214 capable of providing a coating (e.g., an electroplated coating or PVD defined coating) to the surface of the component 210. An example coating system 300 is discussed in reference to FIG. 5. After providing a coating (e.g., an electroplated coating or PVD defined coating) the component 210 becomes a coated component 230.

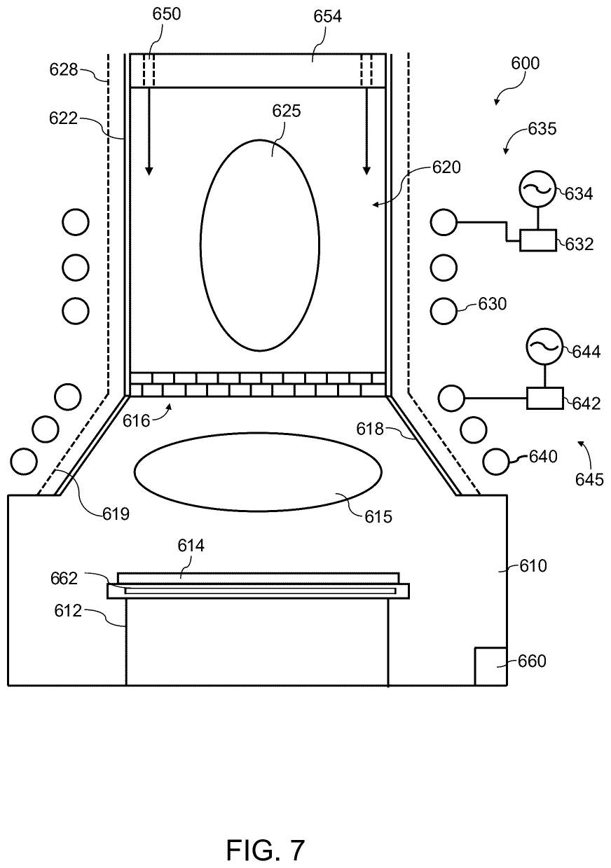

At 218, the method 200 involves providing the coated component 230 to a plasma processing system 220, such as the example plasma processing system 100 of FIG. 1, or any of the example plasma processing systems of FIGS. 7 through 14. At 219, the method 200 optionally includes anodizing the surface of the coated component 230, which may produce the coated component 230 with an anodized coating. The anodized coating of the coated component 230 may be produced by electrochemical systems and/or oxidation systems, such as the example coating system 300 of FIG. 5.

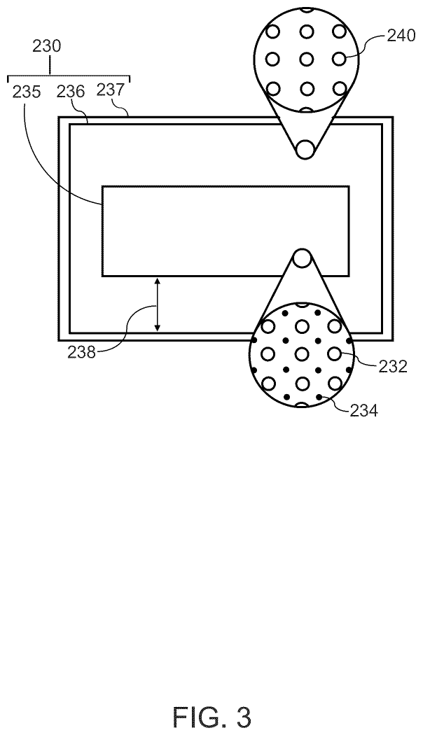

FIG. 3 depicts the coated component 230 after undergoing a coating process, such as an electrochemical coating process, according to aspects of the present disclosure. The coated component 230 may include a metal 235, such as an alloy (e.g., the metal 235 containing a bulk material element 232 and one or more of an alloying element 234) or the metal 235 may contain primarily the bulk material element 232 (e.g., the metal 235 may lack the one or more alloying elements 234). An alloy containing the bulk material element 232 and the alloying elements 234 is demonstrated, for illustrative purposes, in the magnified view of the structure of the metal 235 of FIG. 3. In some embodiments, the metal 235 may have a bulk material element 232 (e.g., aluminum, copper, etc.) with one or more of the alloying elements 234 (e.g., iron, copper, silicon, etc.). The one or more alloying elements 234 of the metal 235 are shown occupying interstitial sites for illustrative purposes only, it will be understood by one skilled in the art, using the disclosures provided herein, that any alloying mechanism may be employed by the one or more alloying elements 234 in relation to the bulk material element 232. In some embodiments, the metal 235 may lack the one or more alloying elements 234 and may contain primarily the bulk material element 232.

The coated component 230 may have a coating 236 on the surface of the metal 235. The coating 236 may provide a protective barrier layer to the component 210, wherein the metal 235 and any bulk material element 232 or alloying element 234 are protected from the environment created in a plasma processing system, such as the plasma processing system 100 of FIG. 1, or any of the plasma processing systems of FIGS. 7 through 14. The coating 236 may have a thickness 238 in a range of about 2 microns to about 400 microns, such as in a range of about 5 microns to about 200 microns, such as about 10 microns to about 100 microns, such as about 10 microns, such as about 100 microns on any surface of the metal 235. In some embodiments, the coating 236 may cover all surfaces of the coated component 230 as illustrated in FIG. 3.

In some embodiments, the coating 236 may be selectively applied to features or desired surfaces of the metal 235. For instance, the coating 236 may be provided to a first portion (e.g., a first surface) of the metal 235 and not applied to a second portion (e.g., a second surface) of the metal 235. In some examples, the coating may be applied to a first portion of a surface (e.g., a central portion) of the metal 235 and not applied to a second portion of the surface (e.g., a peripheral portion) of the metal 235. In some examples, the coating may not be applied to the first portion of the surface (e.g., the central portion) of the metal 235 but is applied to the second portion of the surface (e.g., central portion) of the metal 235.

In some embodiments, the coating 236 may additionally include an anodized coating 237. The anodized coating 237 may include an oxide thickness of at least about 2 micrometers to about 200 micrometers in thickness.

As illustrated in the magnified view of the metal structure of the coating 236 in FIG. 3, the coating may have a coating bulk material element 240 that is the same as the bulk material element 232 of the metal 235 the coating 236 is applied to (e.g., the primary element of the coating 236 may be the same as the primary element of the bulk material element 232 of the metal 235). In some embodiments, the coating 236 may have the coating bulk material element 240 that is the different than the bulk material element 232 of the metal 235 the coating 236 is applied to (e.g., the primary element of the coating 236 may differ from the primary element of the bulk material element 232 of the metal 235).

FIGS. 4A-4D depict an example thermal structure 244 provided as part of a workpiece support 242 according to example embodiments of the present disclosure. FIG. 4A depicts the workpiece support 242 that includes the thermal structure 244 according to aspects of the present disclosure. The workpiece support 242 may include a primarily flat surface 246 on which a workpiece may be processed. The workpiece support 242 may include a stem structure 248 that supports the primarily flat surface 246 of the workpiece support 242. In some embodiments, the workpiece support 242 includes the thermal structure 244, such as the thermal structure 118 of FIG. 1 or any of the thermal structures that may be present in the plasma processing systems of FIGS. 7 through 14. In some embodiments, the thermal structure 244 may be a cooling channel or a heater (e.g., an electrically resistive heating structure) that is operable to alter the temperature of a workpiece or the workpiece support during a plasma processing operation. In some embodiments, the thermal structure 244 may be made of copper or other thermally conductive material.

FIG. 4B depicts the example thermal structure 244 provided as part of the workpiece support 242 according to example embodiments of the present disclosure. In some embodiments, the thermal structure 244 may undergo application of the coating 236 to produce a coated structure 250. The coated structure 250 may be provided to the workpiece support 242. In some embodiments, the coated structure 250 may be disposed substantially within the workpiece support 242, or may have exposed surfaces (e.g., the coating 236 may be exposed within the plasma processing system, such as the plasma processing system 100 of FIG. 1, or any of the plasma processing systems of FIGS. 7 through 14). In some embodiments, the thermal structure 244 may be one or more cooling channels or heaters (e.g., electrically resistive heaters). In some embodiments, the thermal structure 244 may be made of copper or other thermally conductive material. In some embodiments, the coating 236 may be an electroplated coating (e.g., an anodized electroplated coating). In some embodiments, the coating 236 may be a PVD defined coating. In some embodiments, the coating 236 may include an aluminum coating.

In some embodiments, the aluminum coating may have a purity of at least about 90%, such as at least about 95%, such as at least about 97.5%, such as at least about 99.99%, such as in a range of about 90% to about 99.99%. In some embodiments, the coating 236 has a thickness of at least about 10 microns, such as in a range of about 2 microns to about 400 microns, such as in a range of about 5 microns to about 200 microns, such as about 10 microns to about 100 microns, such as about 10 microns, such as about 100 microns. In some embodiments, the coated structure 250 may be anodized (e.g., an anodized electroplated coating). In some examples, the coating is an anodized aluminum coating. In some examples, the anodized aluminum coating comprises an oxide layer of at least about at least about 2 micrometers to about 200 micrometers in thickness.

FIG. 4C depicts the example workpiece support 242 according to example embodiments of the present disclosure. In some embodiments, the workpiece support 242 may undergo application of the coating 236 to produce the coated structure 250. In some embodiments, the workpiece support 242 may include thermal structures 244 (e.g., cooling channels or heaters) operable to alter the temperature of a workpiece during a plasma processing operation. In some embodiments, the thermal structures 244 may additionally include the coating 236 as discussed in reference to FIGS. 4B and 4D. In some embodiments, the coating 236 is an electroplated coating (e.g., an anodized electroplated coating) or PVD defined coating that contains a material that is the same as a bulk material element of the workpiece support 242. In some embodiments, the coating 236 includes an aluminum coating. In some embodiments, the aluminum coating has a purity of at least about 90%, such as at least about 95%, such as at least about 97.5%, such as at least about 99.99%, in a range of about 90% to about 99.99%. In some embodiments, the coating has a thickness of at least about 10 microns, such as in a range of about 2 microns to about 400 microns, such as in a range of about 5 microns to about 200 microns, such as about 10 microns to about 100 microns, such as about 10 microns, such as about 100 microns. In some embodiments, the component with the coating is anodized (e.g., an anodized coating). In some examples, the aluminum coating is an anodized aluminum coating. In some embodiments, the anodized aluminum coating comprises an oxide layer of at least about 2 micrometers to about 200 micrometers in thickness.

The coated structure 250 of FIG. 4C is for illustrative purposes only and does not encompass the variety of surface features the coating 236 may be applied to in order to create the coated structure 250. For instance, the coating 236 may be provided to a first portion (e.g., a first surface) of the workpiece support 242 and not applied to a second portion (e.g., a second surface) of the workpiece support 242. In some examples, the coating 236 may be applied to a first portion of a surface (e.g., a central portion) of the workpiece support 242 and not applied to a second portion of the surface (e.g., a peripheral portion) of the workpiece support 242. In some examples, the coating 236 may not be applied to the first portion of the surface (e.g., the central portion) of the workpiece support 242 but is applied to the second portion of the surface (e.g., central portion) of the workpiece support 242.

FIG. 4D depicts the example thermal structure 244 provided as part of the workpiece support 242 according to example embodiments of the present disclosure. In some embodiments, the thermal structure 244 may include the coating 236 of sufficient thickness such that the interface between the thermal structure 244 and the workpiece support 242 provides enhanced contact. This may increase the temperature flow between the thermal structure 244 and the workpiece support 242, enhancing the ability of the workpiece support 242 with the coated structure 250 to alter the temperature of a workpiece relative to a workpiece support lacking the coated structure 250.

In some embodiments, the coated structure 250 may be disposed substantially within the workpiece support 242, or may have exposed surfaces (e.g., the coating 236 may be exposed within the plasma processing system, such as the plasma processing system 100 of FIG. 1, or any of the plasma processing systems of FIGS. 7 through 14). In some embodiments, the thermal structure 244 may be one or more cooling channels or heaters (e.g., electrically resistive heaters). In some embodiments, the thermal structure 244 may be made of copper or other thermally conductive material. In some embodiments, the coating 236 may be an electroplated coating (e.g., an anodized electroplated coating). In some embodiments, the coating 236 may be a PVD defined coating. In some embodiments, the coating 236 may include an aluminum coating. In some embodiments, the aluminum coating may have a purity of at least about 90%, such as at least about 95%, such as at least about 97.5%, such as at least about 99.99%, such as in a range of about 90% to about 99.99%.

In some embodiments, the coating 236 has a thickness of at least about 10 microns, such as in a range of about 2 microns to about 400 microns, such as in a range of about 5 microns to about 200 microns, such as about 10 microns to about 100 microns, such as about 10 microns, such as about 100 microns. In some embodiments, the coated structure 250 may be anodized (e.g., an anodized electroplated coating). In some examples, the aluminum coating is an anodized aluminum coating. In some examples, the anodized aluminum coating comprises an oxide layer of at least about 2 micrometers to about 200 micrometers in thickness.

FIG. 5 depicts an example coating system 300 according to aspects of the present disclosure. The example coating system 300 may be an electrochemical coating system, such as an electrolytic coating system capable of applying a coating, such as the coating 236 of FIG. 3. The example coating system 300 may include a cell 310, which may be closed to the environment. The cell 310 may contain a solvent-based electrolyte 312. The solvent-based electrolyte 312 may include an organic solvent. The solvent-based electrolyte 312 may contain the metal to be deposited (e.g., the bulk material element 232) or conductive salts that improve electrochemical stability of the solvent-based electrolyte 312. The cell 310 may contain an anode 314 which may have the same chemical composition as the bulk material element 232 of the component 210 (e.g., the metal 235 of the component 210 to be coated). The anode 314 may have a different chemical composition as the bulk material element 232 of the component 210 (e.g., the metal 235 of the component 210 to be coated). The cell 310 may contain a cathode 316, which may be the component 210 to be coated. The anode 314 and the cathode 316 may be placed in the cell 310 in any spatial relationship to one another.

The anode 314 and the cathode 316 may be connected to a source 318 capable of generating electric voltage, such as a rectifier. When the solvent-based electrolyte 312 is electrified, atoms at the surface of the anode 314 may be provided an energetic incentive to migrate to and deposit on the surface of the cathode 316. The uniformity of the thickness 238 of the coating 236 may be controlled by the electrochemical stability of the solvent-based electrolyte 312.

In some embodiments, the coated component 230 may include an anodized electroplated coating. The example coating system 300 of FIG. 5 may provide the anodized coating after application of the electroplated coating. In an anodization process, oxygen ions are released from the electrolyte, such as the solvent-based electrolyte 312 of FIG. 5 and are energetically motivated to combine with the atoms at the surface of the coated component 230 (e.g., with the atoms of the coating 236 of FIG. 3A) to produce an oxide layer, or an anodized electroplated coating.

FIG. 5 depicts one example coating system that may be used to apply a coating to a component of a plasma processing system according to examples of the present disclosure. Those of ordinary skill in the art, using the disclosures provided herein, will understand that other coating systems/processes may be used without deviating from the scope of the present disclosure.

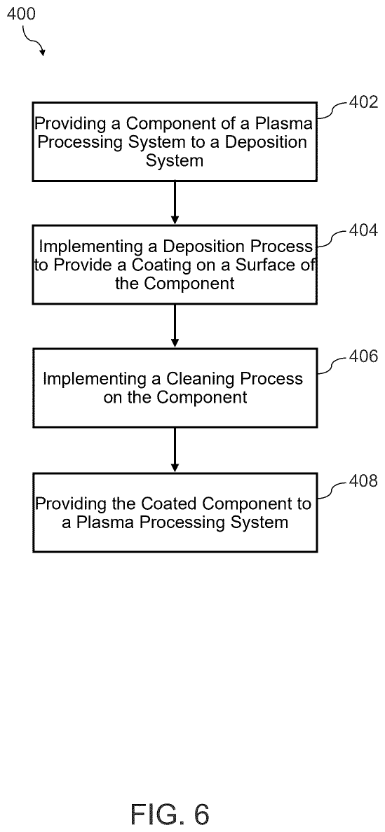

FIG. 6 depicts a flowchart diagram of an example method 400 for manufacturing or preparing a component for use in a plasma processing system, according to example aspects of the present disclosure. While the operations are illustrated in a particular order for purposes of discussion, those of ordinary skill in the art, using the disclosures provided herein, will understand that the various steps of method 400 may be adapted, rearranged, omitted, or include additional steps not illustrated (such as surface preparation, additional cleaning, etc.) without deviating from the scope of the present disclosure.

The method 400 at 402 includes providing a component of a plasma processing system to a deposition system or other suitable system for providing a coating. At 404, the method 400 includes implementing a deposition process to provide a coating on a surface of the component, thereby producing a coated component. This deposition process, such as those described herein, is selected to form a dense, uniform, and high-purity layer on the component's surfaces. In some examples, the deposition process is an electrochemical process, such as electroplating. In some examples, the deposition process is, for instance, a PVD process. It is noted that a preliminary cleaning or surface preparation step may also be performed prior to 404 to provide enhanced coating adhesion and quality.

Following the deposition process, the method 400 may optionally include, at 406, implementing a cleaning process on the component. This cleaning process serves to remove any residual contaminants from the deposition process and to prepare or passivate the final surface. For instance, the cleaning process can include exposing the component to nitric acid, for example by immersing the component in a nitric acid bath for a predetermined time. Washing of the component, for example with deionized water, can be performed both before and/or after the nitric acid exposure to ensure a clean, residue-free surface. In some embodiments, the nitric acid treatment may also serve to provide passivation of the coated surface, creating a more stable and non-reactive final layer. The cleaning process may be performed prior to the coating process without deviating from the scope of the present disclosure.

At 408, after the component has been coated and optionally cleaned, the method 400 concludes by providing the coated component to a plasma processing system. This operation may involve the installation or assembly of the finished component into its operational position within a plasma processing apparatus. Example plasma processing systems into which the coated component may be integrated are discussed in reference to FIG. 1, and any of the systems of FIGS. 7 through 14. Once installed, the coated component is ready for use in processing semiconductor workpieces, where its coated surface provides the functional benefits of improved plasma uniformity, reduced particle generation, and enhanced component lifetime.

FIG. 7 depicts an example plasma processing apparatus 600 according to example embodiments of the present disclosure. The plasma processing apparatus 600 can include a processing chamber 610 and a plasma chamber 620 that is separate from the processing chamber 610. The plasma chamber 620 can be disposed in a vertical position above the processing chamber 610.

The processing chamber 610 can include a pedestal, substrate holder, or workpiece support 612 operable to support a workpiece 614. The workpiece support 612 can include one or more structures 662 (e.g., heaters, cooling channels, electrostatic chucks, bias electrodes, etc.). In some embodiments, the pedestal 612 can be movable in a vertical direction as will be discussed in more detail below.

The apparatus 600 can include a first plasma source 635 that is operable to generate a remote plasma 625 in a process gas provided in the plasma chamber 620. Desired species (e.g. neutral species) can then be channeled from the plasma chamber 620 to the surface of the workpiece 614 through holes provided in a separation grid 616 that separates the plasma chamber 620 from the processing chamber 610 (i.e., downstream region).

The plasma chamber 620 includes a dielectric side wall 622. The plasma chamber 620 includes a top plate 654. The dielectric side wall 622 and the top plate 654 define a plasma chamber interior. The dielectric side wall 622 can be formed from any dielectric material, such as quartz.

The first plasma source 635 can include an induction coil 630 disposed adjacent the dielectric side wall 622 about the plasma chamber 620. The induction coil 630 can be coupled to an RF power generator 634 through a suitable matching network 632. Reactant and carrier gases can be provided to the chamber interior from a gas supply 650. When the induction coil 630 is energized with RF power from the RF power generator 634, a remote plasma can be induced in the plasma chamber 620. The plasma processing apparatus 600 can include a grounded Faraday shield 628 to reduce capacitive coupling of the induction coil 630 to the remote plasma 625.

The separation grid 616 separates the plasma chamber 620 from the processing chamber 610. The separation grid 616 can be used to perform ion filtering of species generated by remote plasma 625 in the plasma chamber 620. Species passing through the separation grid 616 can be exposed to the workpiece 614 (e.g. a semiconductor wafer) in the processing chamber 610 for plasma processing of the workpiece 614 (e.g., photoresist removal).

More particularly, in some embodiments, the separation grid 616 can be transparent to neutral species but not transparent to charged species from the plasma. For example, charged species or ions can recombine on walls of the separation grid 616. The separation grid 616 can include one or more grid plates of material with holes distributed according to a hole pattern for each sheet of material. The hole patterns can be the same or different for each grid plate.

For example, the holes can be distributed according to a plurality of hole patterns on a plurality of grid plates arranged in a substantially parallel configuration such that no hole allows for a direct line of sight between the plasma chamber 620 and the processing chamber 610 to, for example, reduce or block UV light. Depending on the process, some or all of the separation grid 616 can be made of a conductive material (e.g., Al, Si, SiC, etc.) and/or non-conductive material (e.g., quartz, etc.). In some embodiments, if a portion of the separation grid 616 (e.g. a grid plate) is made of a conductive material, the portion of the separation grid 616 can be grounded. In some embodiments, the separation grid 616 can be configured for post plasma gas injection.

Referring to FIG. 7, the processing chamber 610 can include a dielectric window 618. The dielectric window 618 can flare outward and together with the separation grid 616 from at least a portion of a ceiling of the processing chamber 610. The separation grid 616 may be positioned at a junction between the dielectric side wall 622 of the plasma chamber 620 and the dielectric window 618 of the processing chamber 610, and the dielectric window 618 can flare outwardly as the dielectric window 618 extends downwardly from the separation grid 616. Due to the flaring of the dielectric window 618, a width of the processing chamber 610 along a horizontal direction may be greater than a width of the plasma chamber 620 along the horizontal direction. The dielectric window 618 can be made from any suitable dielectric material, such as quartz. The dielectric window 618 of the processing chamber 610 may be separate from or integrally formed with the dielectric side wall 622 of the plasma chamber 620.

The plasma processing apparatus 600 includes a second plasma source 645. The second plasma source 645 can be operable to generate a direct plasma 615 in the processing chamber 610. For instance, when the first plasma source 635 is not used to generate a remote plasma 625, the plasma chamber 620 and/or the separation grid can act as a showerhead to provide process gas to the processing chamber 610. The second plasma source 645 can be used to generate a direct plasma 615 in the process gas. Ions, neutrals, radicals, and other species generated in the direct plasma 615 can be used for plasma processing of the workpiece 614. When the first plasma source 635 is used to generate the remote plasma 625, the second plasma source can be used to generate the direct plasma 615 by re-dissociating radicals passing through the separation grid 616.

The second plasma source 645 can include an induction coil 640 disposed adjacent the dielectric window 618. The induction coil 640 can be coupled to an RF power generator 644 through a suitable matching network 642. The RF generator 644 can be independent from RF generator 634 to provide for independent control of source power (e.g., RF power) for the first plasma source 635 and the second plasma source 645. However, in some embodiments, the RF generator 644 can be the same as the RF generator 634 for the first plasma source 635. The plasma processing apparatus 600 can include a grounded Faraday shield 619 to reduce capacitive coupling of the induction coil 640 to the direct plasma 615. In some embodiments, the Faraday shield 619 can mechanically support induction coil 640.

The induction coil 640 of the second plasma source 645 can also assist with controlling uniformity within the processing chamber 610. For instance, the induction coils 630, 640 can be independently operable to control the plasma density distribution adjacent induction coils 630, 640. In particular, the RF power generator 634 may be operable to independently adjust the frequency, average peak voltage or both of the RF power to the induction coil 630 of the first plasma source 635, and the RF power generator 644 may be operable to independently adjust the frequency, average peak voltage or both of the RF power to the induction coil 640 of the second plasma source 645. Thus, the plasma processing apparatus 600 may have improved source tunability.

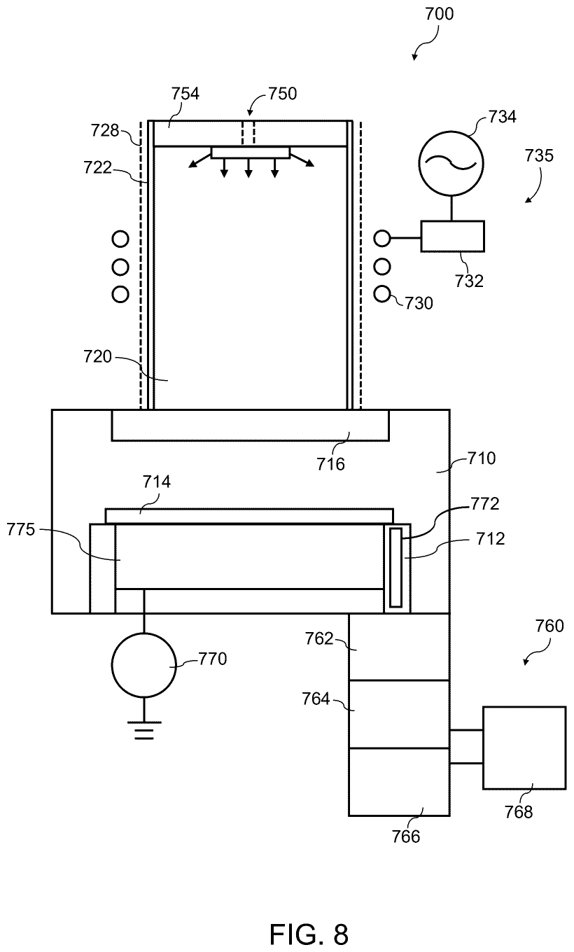

The plasma processing apparatus 600 can further include one or more pump systems 660 configured to control pressure within the processing chamber 610 and/or evacuate gases from the processing chamber 610. Details concerning example pump systems will be discussed in greater detail below in the context of FIG. 8.

In certain example embodiments, the plasma processing apparatus 600 includes features for vertical tunability of process uniformity. More particularly, a distance between a workpiece in a processing chamber and a separation grid is adjustable. For instance, in some example embodiments, a position of the substrate holder 612 is adjustable along a vertical direction to adjust the distance between the workpiece 614 on the substrate holder 612 and the separation grid 616. In other example embodiments, one or more lift pins can be used to lift the workpiece 614 and adjust the distance between the workpiece 614 and the separation grid 616.

Performance of plasma processing apparatus 600 can be improved relative to known plasma processing tools by adjusting the distance between the workpiece 614 and the separation grid 616. For instance, the distance between the workpiece 614 and the separation grid 616 can be adjusted to provide a suitable distance for a process, such as a photoresist strip process and/or a plasma etch process. As another example, the distance between the workpiece 614 and the separation grid 616 can be adjusted to provide adjustable and/or dynamic cooling of the workpiece 614. In certain example, embodiments, the workpiece 614 may remain within the plasma processing apparatus 600 between different plasma processing operations, and the distance between the workpiece 614 and the separation grid 616 can be adjusted between the various plasma processing operations to provide a suitable distance for the current plasma processing operation.

The plasma processing apparatus 600 may include one or more components with a coating, such as an electroplated coating (e.g., an anodized electroplated coating) or a PVD defined coating. For instance, one or more of the separation grid 616, the thermal structure 662, the workpiece support 612, or other component may include a coating according to aspects of the present disclosure.

FIG. 8 depicts an example plasma processing apparatus 700 according to example embodiments of the present disclosure. The plasma processing apparatus 700 includes numerous common components with plasma processing apparatus 600 (FIG. 7). For example, the plasma processing apparatus 700 includes a processing chamber 710, a substrate holder or workpiece support 712, a thermal structure 772, a separation grid 716, a plasma chamber 720, a dielectric side wall 722, a grounded Faraday shield 728, a gas supply 750 and a top plate 754. The plasma processing apparatus 700 may also include a plasma source 735 with an induction coil 730, a matching network 732 and an RF power generator 734. Thus, the plasma processing apparatus 700 may also operate in a similar manner to that described above for plasma processing apparatus 600 of FIG. 7. In particular, the plasma source 735 may be operable to generate a remote plasma in the plasma chamber 720. It will be understood that the components of the plasma processing apparatus 700 shown in FIG. 8 may also be incorporated into any other suitable plasma processing apparatus in alternative example embodiments. As discussed in greater detail below, the plasma processing apparatus 700 includes features for generating a direct plasma in the processing chamber 710.

In the plasma processing apparatus 700, an RF bias source 770 is coupled to an electrostatic chuck or bias electrode 775. The bias electrode 775 may be positioned below separation grid 716 within the processing chamber 710. For example, the bias electrode 775 may be mounted to the workpiece support 712. The RF bias source 770 is operable to supply RF power to the bias electrode 775. When the bias electrode 775 is energized with RF power from the RF bias source 770, a direct plasma can be induced in the processing chamber 710.

The RF bias source 770 is operable at various frequencies. For example, the RF bias source 770 may energize the bias electrode 775 with RF power at frequency of about 13.56 MHZ Thus, the RF bias source 770 may energize the bias electrode 775 to form a direct capacitively coupled plasma within the processing chamber 710. In certain example embodiments, the RF bias source 770 may be operable to energize the bias electrode 775 with RF power at frequencies in a range between about 400 KHz and about 60 KHz.

As may be seen from the above, the plasma processing apparatus 700 may have a radical source (e.g., the plasma source 735) positioned above the separation grid 716 and may also have the bias electrode 775 positioned below the separation grid 716. Thus, the induction coil 730 and the bias electrode 775 may be positioned opposite each other about the separation grid 716. In such a manner, the plasma processing apparatus 700 may form a remote plasma within the plasma chamber 720 and may also form a direct plasma within the processing chamber 710.

When the plasma source 735 is deactivated, the separation grid 716 and the plasma chamber 720 may act as a gas mixing showerhead for the gas injection into the processing chamber 710. Thus, when the plasma source 735 is not operating to form the remote plasma, the components of the plasma processing apparatus 700 above the processing chamber 710 may assist with forming the direct plasma within the processing chamber 710. When the plasma source 735 operates to form the remote plasma within the plasma chamber 720 and the RF bias source 770 energizes the bias electrode 775 to form a direct plasma within the processing chamber 710 (i.e., when both the RF power generator 734 and the RF bias source 770 are turned on), the radicals generated from the remote plasma within the plasma chamber 720 can be re-dissociated by the bottom bias on the workpiece 714 provided by bias electrode 775.

The plasma processing apparatus 700 may also include a turbopump assembly 760. The turbopump assembly 760 may have a pressure control valve 762, a pumping selection control valve 764, a turbopump 766 and a foreline pump 768. The pressure control valve 762 can be configured to adjust or regulate pressure within the turbopump assembly 760 and/or the processing chamber 710. The pumping selection control valve 764 can be manually and/or automatically operable to select between one or more pumps, such as the turbopump 766 and the foreline pump 768, to provide a pumping action to the processing chamber 710. For example, the pumping selection control valve 764 can open a connection to one connected pump while closing one or more connections to one or more other connected pumps.

The turbopump 766 can be a turbomolecular pump with a plurality of stages that each includes a rotating rotor blade and a stationary stator blade. The turbopump 766 can intake gas (e.g. from the process chamber 710) at the uppermost stage, and the gas can be pushed to the lowermost stage through various rotor blades and stator blades of the turbopump 766. The turbopump 766 can be independently powered and/or can be powered by the foreline pump 768. For example, the turbopump 766 can be driven using pressure created by the foreline pump 768 as a backing pump. In particular, the foreline pump 768 can create pressure at a lower end of the turbopump 766, causing the rotor blades in the turbopump 766 to spin, thus causing the pumping action associated with the turbopump 766.

Additionally, the foreline pump 768 can be directly connected to the pumping selection control valve 764. For example, the pumping selection control valve 764 can be operable to select the foreline pump 768 to provide high pressure (e.g., about 100 mTorr to about 10 Torr) within the processing chamber 710. The pumping selection control valve 764 can additionally be operable to select the turbopump 766 to provide low pressure (e.g., about 5 mTorr to about 100 mTorr) within the processing chamber 710.

The plasma processing apparatus 700 may include one or more components with a coating, such as an electroplated coating (e.g., an anodized electroplated coating) or a PVD defined coating. For instance, one or more of the separation grid 716, the thermal structure 772, the workpiece support 712, or other component may include a coating according to aspects of the present disclosure.

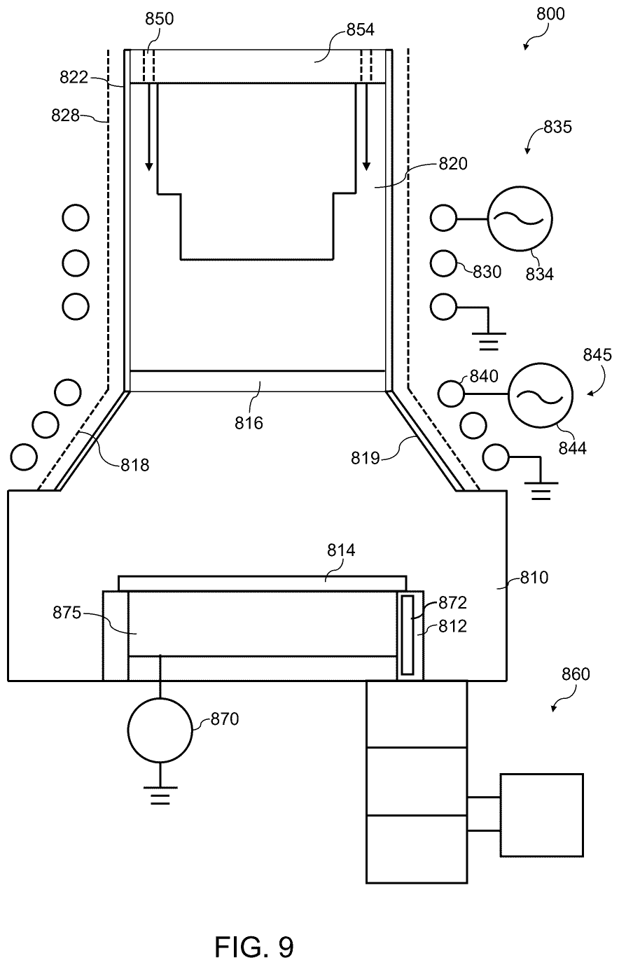

FIG. 9 depicts an example plasma processing apparatus 800 according to example embodiments of the present disclosure. The plasma processing apparatus 800 includes numerous common components with the plasma processing apparatus 600 (FIG. 7) and plasma processing apparatus 700 (FIG. 8). For example, the plasma processing apparatus 800 includes a processing chamber 810, a workpiece support 812, a thermal structure 872, a separation grid 816, a plasma chamber 820, a dielectric side wall 822, a grounded Faraday shield 828, a gas supply 850, a top plate 854, and a turbopump assembly 860. The plasma processing apparatus 800 may also include a first plasma source 835 with an induction coil 830 and an RF power generator 834. Thus, the plasma processing apparatus 800 may operate in a similar manner to that described above for the plasma processing apparatus 600 and plasma processing apparatus 700 of FIGS. 8 and 9. In particular, the plasma source 835 may be operable to generate a remote plasma in plasma chamber 820. It will be understood that the components of the plasma processing apparatus 800 shown in FIG. 9 may also be incorporated into any other suitable plasma processing apparatus in alternative example embodiments. As discussed in greater detail below, the plasma processing apparatus 800 includes features operable to generate a direct plasma in the processing chamber 810.

In the plasma processing apparatus 800, a second plasma source 845 includes an induction coil 840 and an RF power generator 844. As described above in the context of the plasma processing apparatus 600 of FIG. 7, the second plasma source 845 can be operable to generate a direct plasma in the processing chamber 810. For instance, the induction coil 840 of the second plasma source 845 may be disposed adjacent a dielectric window 818. The induction coil 840 can be coupled to the RF power generator 844 that is operable to energize the induction coil 840 and thereby generate the direct plasma in the processing chamber 810. The plasma processing apparatus 800 can also include a grounded Faraday shield 819 to reduce capacitive coupling of the induction coil 840 to the direct plasma. The second plasma source 845 of plasma processing apparatus 800 may be constructed in the same or similar manner to that described above for the second plasma source 645 of plasma processing apparatus 600 of FIG. 7. Thus, the plasma processing apparatus 800 may also operate in a similar manner to that described above for plasma processing apparatus 600 of FIG. 7 to generate a direct plasma in the processing chamber 810.

The plasma processing apparatus 800 may further include an RF bias source 870 and an electrostatic chuck or bias electrode 875. As described above in the context of plasma processing apparatus 700, the RF bias source 870 is coupled to the bias electrode 875. When the bias electrode 875 is energized with RF power from the RF bias source 870, a direct plasma can be induced in the processing chamber 810. The RF bias source 870 and the bias electrode 875 of the plasma processing apparatus 800 may be constructed in the same or similar manner to that described above for the RF bias source 770 and bias electrode 775 of plasma processing apparatus 700 of FIG. 8. Thus, the plasma processing apparatus 800 may also operate in a similar manner to that described above for the plasma processing apparatus 700 of FIG. 8 to generate a direct plasma in the processing chamber 810.

As may be seen from the above, the plasma processing apparatus 800 may include a second plasma source 845, an RF bias source 870 and a bias electrode 875 to generate a direct plasma in the processing chamber 810. The plasma source 845 may be operated simultaneously with the RF bias source 870 and the bias electrode 875 to generate the direct plasma in the processing chamber 810. The plasma source 845 and the bias source 870 or the bias electrode 875 may also be operated independently of each other to generate the direct plasma in the processing chamber 810.

The plasma processing apparatus 800 may include one or more components with a coating, such as an electroplated coating (e.g., an anodized electroplated coating) or a PVD defined coating. For instance, one or more of the separation grid 816, the thermal structure 872, the workpiece support 812, or other component may include a coating according to aspects of the present disclosure.

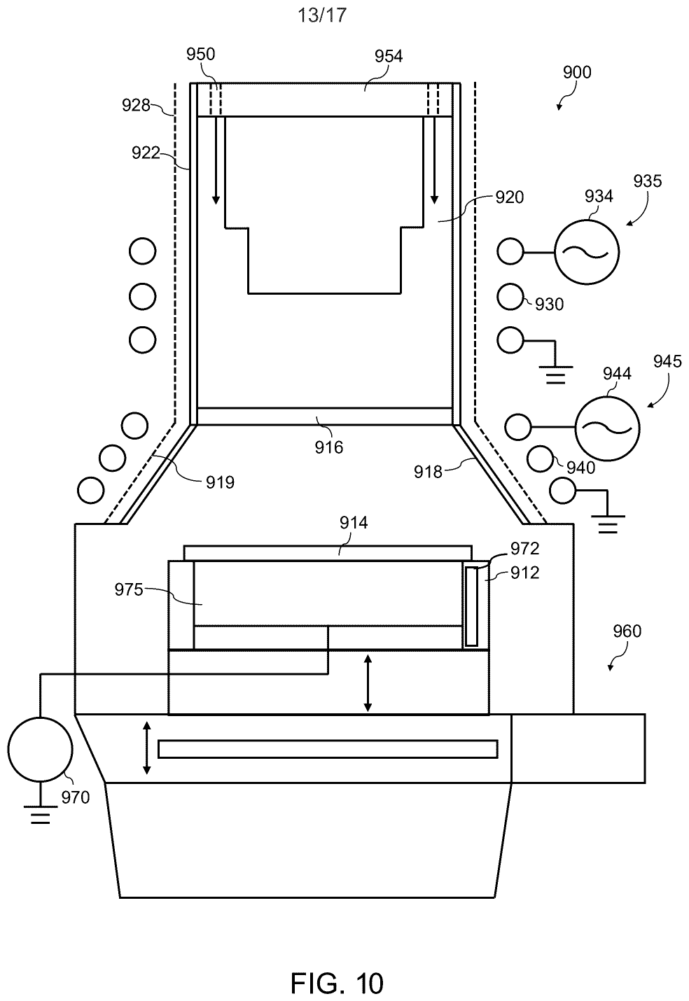

FIG. 10 depicts an example plasma processing apparatus 900 according to example embodiments of the present disclosure. The plasma processing apparatus 900 includes numerous common components with the plasma processing apparatus 600 (FIG. 7), plasma processing apparatus 700 (FIG. 8), and plasma processing apparatus 800 (FIG. 9). For example, the plasma processing apparatus 900 includes a processing chamber 910, a workpiece support 912, a separation grid 916, a plasma chamber 920, a dielectric side wall 922, a grounded Faraday shield 928, a gas supply 950, a top plate 954, and a turbopump assembly 960. The plasma processing apparatus 900 may also include a first plasma source 935 with an induction coil 930 and an RF power generator 934. Thus, the plasma processing apparatus 900 may also operate in a similar manner to that described above for the plasma processing apparatus 600 of FIG. 7 and the plasma processing apparatus 700 of FIG. 8. In particular, the plasma source 935 may be operable to generate a remote plasma in the plasma chamber 920. It will be understood that the components of the plasma processing apparatus 900 shown in FIG. 10 may also be incorporated into any other suitable plasma processing apparatus in alternative example embodiments.

The plasma processing apparatus 900 includes features for generating a direct plasma in the processing chamber 910. For example, the plasma processing apparatus 900 includes a second plasma source 945 with an induction coil 940 and an RF power generator 944. As described above in the context of the plasma processing apparatus 600 of FIG. 7, the second plasma source 945 can be operable to generate a direct plasma in the processing chamber 910. For instance, the induction coil 940 of the second plasma source 945 may be disposed adjacent a dielectric window 918. The induction coil 940 can be coupled to the RF power generator 944 that is operable to energize the induction coil 940 and thereby generate the direct plasma in the processing chamber 910. The plasma processing apparatus 900 can include a grounded Faraday shield 919 to reduce capacitive coupling of the induction coil 940 to the direct plasma. The second plasma source 945 of the plasma processing apparatus 900 may be constructed in the same or similar manner to that described above for the second plasma source 145 of the plasma processing apparatus 600 of FIG. 7. Thus, the plasma processing apparatus 900 may also operate in a similar manner to that described above for the plasma processing apparatus 600 of FIG. 7 to generate a direct plasma in the processing chamber 910.

The plasma processing apparatus 900 may additionally include an RF bias source 970 and an electrostatic chuck or bias electrode 975. As described above in the context of the plasma processing apparatus 700 of FIG. 8, the RF bias source 970 is coupled to the bias electrode 975. When the bias electrode 975 is energized with RF power from the RF bias source 970, a direct plasma can be induced in the processing chamber 910. The RF bias source 970 and the bias electrode 975 of the plasma processing apparatus 900 may be constructed in the same or similar manner to that described above for the RF bias source 770 and the bias electrode 775 of the plasma processing apparatus 700 of FIG. 8. Thus, the plasma processing apparatus 900 may also operate in a similar manner to that described above for plasma processing apparatus 700 of FIG. 8 to generate a direct plasma in the processing chamber 910.

The plasma processing apparatus 900 also includes features for adjusting a distance between the separation grid 916 or the plasma chamber 920 and a workpiece 914 in the plasma processing apparatus 900. In particular, the workpiece support 1 912 is movable along a vertical direction to adjust a distance between the workpiece 914 and the separation grid 916 or the plasma chamber 920. Thus, the workpiece support 912 may be constructed in the same or similar manner to the pedestal 612 of the plasma processing apparatus 600 of FIG. 7 in order to allow the workpiece support 912 to be positioned at various vertical positions within the processing chamber 910.

The plasma processing apparatus 900 may include one or more components with a coating, such as an electroplated coating (e.g., an anodized electroplated coating) or a PVD defined coating. For instance, one or more of the separation grid 916, the thermal structure 972, the workpiece support 912, or other component may include a coating according to aspects of the present disclosure.

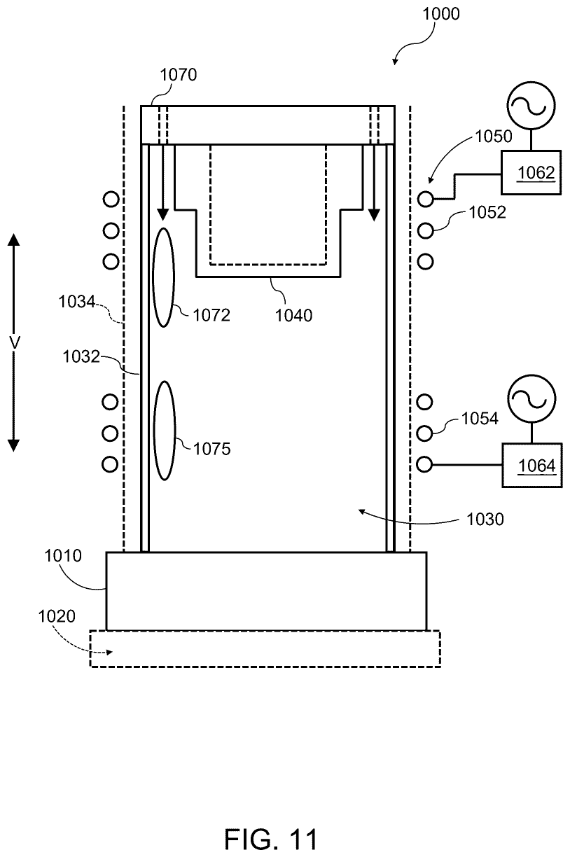

FIG. 11 depicts an example plasma processing apparatus 1000 according to example embodiments of the present disclosure. The plasma processing apparatus 1000 may include a processing chamber 1020 housing a workpiece support and one or more thermal structures (not pictured). The plasma processing apparatus 1000 may include a separation grid assembly 1010 positioned between the processing chamber 1020 and a plasma chamber 1030. A dielectric sidewall 1032 may be positioned between an induction coils 1050 and the plasma chamber 1030. The dielectric sidewall 1032 may have a generally cylindrical shape. A grounded Faraday shield 1034 may also be positioned between an induction coil 1050 and the plasma chamber 1030. For example, the grounded Faraday shield 1034 may be positioned between the induction coils 1050 and the dielectric sidewall 1032. The dielectric sidewall 1032 may contain the inductive plasma within the plasma chamber 1030 while allowing the alternating magnetic field from the induction coils 1050 to pass through to the plasma chamber 1030, and the grounded Faraday shield 1034 may reduce capacitive coupling of the induction coils 1050 to the inductive plasma within the plasma chamber 1030. In certain example embodiments, a density of spaces in the grounded Faraday shield 1034 (e.g., density of shield material relative to holes or spaces) changes along the vertical direction. For example, the density of spaces in the grounded Faraday shield 1034 at or adjacent a first induction coil 1052 may be different than the density of spaces in the grounded Faraday shield 1034 at or adjacent a second induction coil 1054. In particular, the density of spaces in the grounded Faraday shield 1034 at or adjacent the first induction coil 1052 may be more or less than the density of spaces in the grounded Faraday shield 1034 at or adjacent the second induction coil 1054, in certain example embodiments.

As noted above, each of the induction coils 1050 is disposed at a different position along the vertical direction V on the plasma chamber 1030 adjacent a vertical portion of the dielectric sidewall 1032 of the plasma chamber 1030. In this way, each of the induction coils 1050 can be operable to generate a plasma in an active plasma generation region along the vertical surface of the dielectric sidewall 1032 of the plasma chamber 1030.

More particularly, the plasma processing tool 1000 can include a gas injection port 1070 operable to inject process gas at the periphery of the plasma chamber 1030 along a vertical surface of the dielectric sidewall 1032. This can define active plasma generation regions adjacent the vertical surface of the dielectric sidewall 1032. For instance, the first induction coil 1052 can be operable to generate a plasma in a region 1072 proximate a vertical surface of the dielectric sidewall 1032. The second induction coil 1054 can be operable to generate a plasma in a region 1075 proximate a vertical surface of the dielectric sidewall 1032. The gas injection insert 1040, in some embodiments, can further define an active region for generation of the plasma in the plasma chamber 1030 adjacent the vertical surface of the dielectric sidewall 1032.

The plasma processing tool 1000 can have improved source tunability relative to known plasma processing tools. For example, providing two or more of the induction coils 1050 along the vertical surface of the dielectric sidewall 1032 proximate active plasma generation region in the plasma chamber 1030 allows the plasma processing tool 1000 to have improved source tunability. In particular, providing a plurality of the induction coils 1050 in combination with adjusting the density of grounded Faraday shield 1034 along the vertical direction V may facilitate tuning of the inductive plasma at various locations along the vertical direction V. In such a manner, a treatment process performed with the plasma processing tool 1000 on a workpiece may be more uniform.

In some embodiments, the induction coil 1052 and the induction coil 1054 may be coupled to independent RF generators. In this way, the RF power applied to each of the induction coil 1052 and the induction coil 1054 can be independently controlled to tune plasma density in a vertical direction in the plasma chamber 1030.

The plasma processing apparatus 1000 may include one or more components with a coating, such as an electroplated coating (e.g., an anodized electroplated coating) or a PVD defined coating. For instance, one or more of the workpiece support contained within the processing chamber 1020, the gas injection insert 1040, the separation grid assembly 1010, or other component may include a coating according to aspects of the present disclosure.

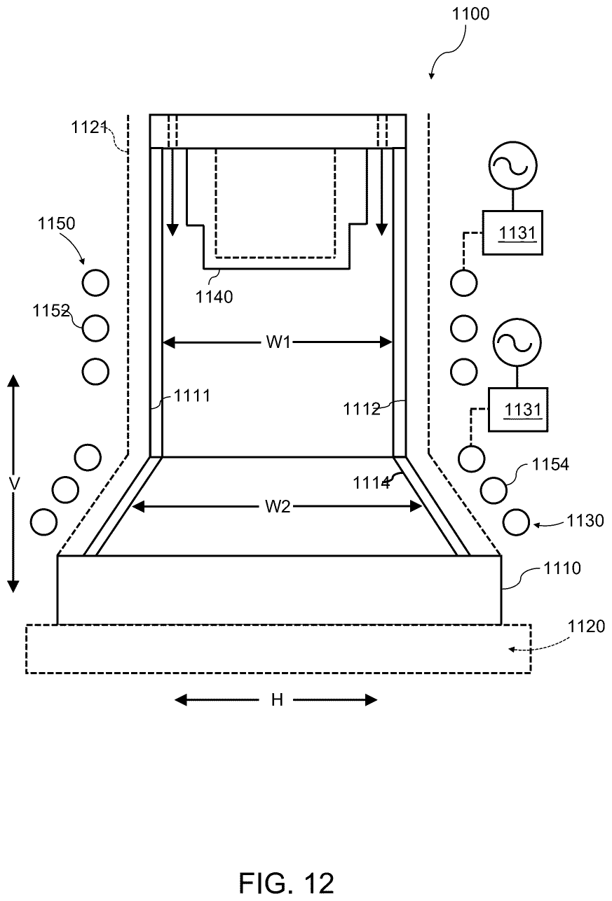

FIG. 12 depicts components of an example plasma processing tool 1100 according to another example embodiment of the present disclosure. The plasma processing tool 1100 includes a separation grid assembly 1110, a processing chamber 1120, a plasma chamber 1130 and induction coils 1150. Thus, plasma processing tool 1100 may also operate in a similar manner to that described above for plasma processing tool 1000 of FIG. 11. It will be understood that the components of the plasma processing tool 1100 shown in FIG. 12 may also be incorporated into any other suitable plasma processing tool in alternative example embodiments. As discussed in greater detail below, the plasma processing tool 1100 includes features for improving source tunability relative to known plasma processing tools.

In the plasma processing tool 1100, a dielectric sidewall 1111 is positioned between the induction coils 1150 and the plasma chamber 1130. The dielectric sidewall 1111 may contain the inductive plasma within the plasma chamber 1130 while allowing the alternating magnetic field from the induction coils 1150 to pass through to the plasma chamber 1130. The dielectric sidewall 1111 may be sized and/or shaped to facilitate source tunability.

The dielectric sidewall 1111 includes a first portion 1112 and a second portion 1114. The second portion 1114 of the dielectric sidewall 1111 flares from the first portion 1112 of the dielectric sidewall 1111. In certain example embodiments, the first portion 1112 of the dielectric sidewall 1111 may be vertically oriented and have a generally cylindrical inner surface that faces the plasma chamber 1130, and the second portion 1114 of the dielectric sidewall 1111 may angled (e.g., not vertical or horizontal) and may have a generally frusto-conical inner surface that faces the plasma chamber 1130. Thus, a width of the plasma chamber 1130 along a horizontal direction H may be greater at the second portion 1114 of the dielectric sidewall 1111 than at the first portion 1112 of the dielectric sidewall 1111.

In particular, the plasma chamber 1130 has a first width W1 along the horizontal direction H at the first portion 1112 of the dielectric sidewall 1111, and the plasma chamber 1130 has a second width W2 along the horizontal direction H at the second portion 1114 of the dielectric sidewall 1111. The second width W2 is greater than the first width W1. In such a manner, the width of the plasma chamber 1130 along the horizontal direction H may be greater at or adjacent the separation grid assembly 1110 relative to the width of the plasma chamber 1130 along the horizontal direction H opposite the separation grid assembly 1110 along the vertical direction V. One of the induction coils 1150 may be positioned at each of the first and the second portions 1112, 1114 of the dielectric sidewall 1111. In particular, the first induction coil 1152 may be positioned at the first portion 1112 of the dielectric sidewall 1111, and the second induction coil 1154 may be positioned at the second portion 1114 of the dielectric sidewall 1111 proximate to the separation grid assembly 1110.

A grounded Faraday shield 1121 may also be positioned between the induction coils 1150 and plasma chamber 1130. For example, the grounded Faraday shield 1121 may be positioned between the induction coils 1150 and the dielectric sidewall 1111. The grounded Faraday shield 1121 may reduce capacitive coupling of the induction coils 1150 to the inductive plasma within the plasma chamber 1130. The grounded Faraday shield 1121 may be a unitary structure. The grounded Faraday shield 1121 may be configured (e.g., sized and/or shaped) to facilitate source tunability. For example, a density of spaces in the grounded Faraday shield 1121 at the first portion 1112 of the dielectric sidewall 1111 may be different than the density of spaces in the grounded Faraday shield 1121 at the second portion 1114 of the dielectric sidewall 1111. In certain example embodiments, the density of spaces in the grounded Faraday shield 1121 at the first portion 1112 of the dielectric sidewall 1111 may be more or less than the density of spaces in the grounded Faraday shield 1121 at the second portion 1114 of the dielectric sidewall 1111. Thus, the density of the grounded Faraday shield 1121 may vary along the vertical direction V.

As discussed above, the induction coils 1150 are operable to generate an inductive plasma within the plasma chamber 1130. In the plasma processing tool 1100, a plurality of the radio frequency power generators 1131 (e.g., RF generators and matching networks) is coupled to the induction coils 1150, and the plurality of radio frequency power generators 1131 are operable to energize the induction coils 1150 to generate the inductive plasma in the plasma chamber 1130. In particular, each of the of radio frequency power generators 1131 may energize a respective one of the induction coils 1150 with an alternating current (AC) of radio frequency (RF) such that the AC induces an alternating magnetic field inside the induction coils 1150 that heats a flow of gas to generate the inductive plasma. Thus, each of the radio frequency power generators 1131 may be coupled to an independent radio frequency power generator 1131 to provide for independent control of RF power to induction coils 1150. Frequency and/or power of RF energy applies using the independent power generators 1131 can be adjusted to be the same or different to control process parameters of a surface treatment process.

The plasma processing tool 1100 can have improved source tunability. For example, proving a plurality of the induction coils 1150 in combination with vertical and angled portions on the dielectric sidewall 1111 allows a user of the plasma processing tool 1100 to have improved source tunability. As another example, adjusting the density of the grounded Faraday shield 1121 along the vertical direction V in combination with providing two or more of the induction coils 1150 allows a user of the plasma processing tool 1100 to have improved source tunability. As yet another example, proving a plurality of the induction coils 1150 in combination with a plurality of the radio frequency power generators 1131 allows a user to adjust one or more of the frequency, voltage, power etc., of the RF energy to the induction coils 1150 to thereby have improved source tunability relative to known plasma processing tools. In such a manner, a plasma processing process performed with the plasma processing tool 1100 on a workpiece can be controlled to be more uniform.

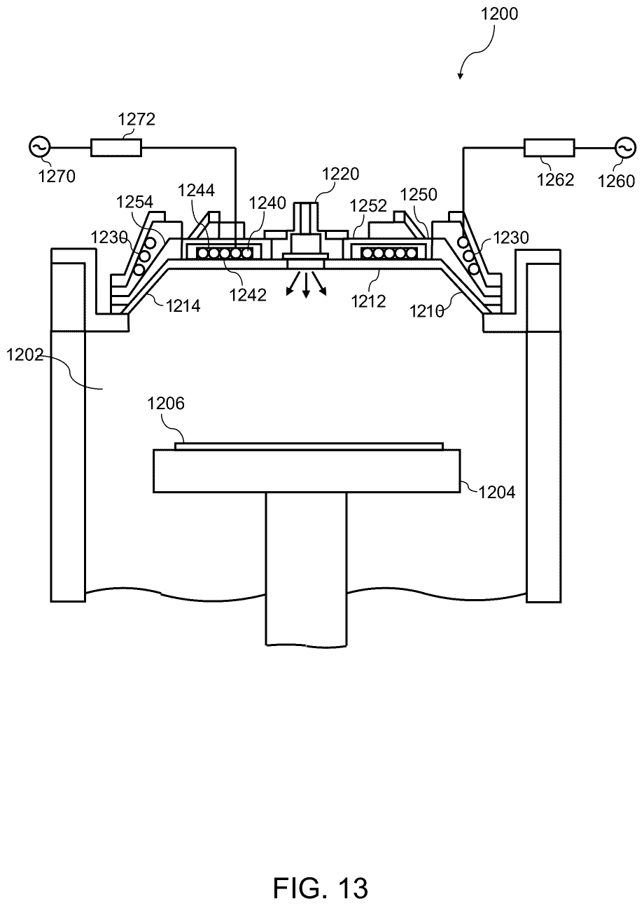

FIG. 13 depicts a plasma processing apparatus 1200 according to an exemplary embodiment of the present disclosure. The plasma processing apparatus 1200 includes a processing chamber defining an interior space 1202. A pedestal, workpiece support, or a substrate holder 1204 is used to support a substrate 1206, such as a semiconductor wafer, within the interior space 1202. A dielectric window 1210 is located above the substrate holder 1204. The dielectric window 1210 includes a relatively flat central portion 1212 and an angled peripheral portion 1214. The dielectric window 1210 includes a space in the central portion 1212 for a showerhead 1220 to feed process gas into the interior space 1202.

The apparatus 1200 further includes a plurality of inductive elements, such as a primary inductive element 1230 and a secondary inductive element 1240, for generating an inductive plasma in the interior space 1202. The inductive elements 1230, 1240 can include a coil or antenna element that when supplied with RF power, induces a plasma in the process gas in the interior space 1202 of the plasma processing apparatus 1200. For instance, a first RF generator 1260 can be configured to provide electromagnetic energy through a matching network 1262 to the primary inductive element 1230. A second RF generator 1270 can be configured to provide electromagnetic energy through a matching network 1272 to the secondary inductive element 1240.

According to aspects of the present disclosure, the apparatus 1200 can include a metal shield portion 1252 disposed around the secondary inductive element 1240. As discussed in more detail below, the metal shield portion 1252 separates the primary inductive element 1230 and the secondary inductive element 1240 to reduce cross-talk between the inductive elements 1230, 1240. The apparatus 1200 can further include a Faraday shield 1254 disposed between the primary inductive element 1230 and the dielectric window. The Faraday shield 1254 can be a slotted metal shield that reduces capacitive coupling between the primary inductive element 1230 and the interior space 1202 of plasma processing apparatus 1200. As illustrated, the Faraday shield 1254 can fit over the angled portion of the dielectric shield 1210.

The arrangement of the primary inductive element 1230 and the secondary inductive element 1240 on opposite sides of the metal shield 1252 allows the primary inductive element 1230 and secondary inductive element 1240 to have distinct structural configurations and to perform different functions. For instance, the primary inductive element 1230 can include a multi-turn coil located adjacent a peripheral portion of the process chamber. The primary inductive element 1230 can be used for basic plasma generation and reliable start during the inherently transient ignition stage. The primary inductive element 1230 can be coupled to a powerful RF generator and expensive auto-tuning matching network and can be operated at an increased RF frequency, such as at about 13.56 MHZ.

The secondary inductive element 1240 can be used for corrective and supportive functions and for improving the stability of the plasma during steady state operation. Since the secondary inductive element 1240 can be used primarily for corrective and supportive functions and improving stability of the plasma during steady state operation, the secondary inductive element 1240 does not have to be coupled to as powerful an RF generator as the first inductive element 1230 and can be designed differently and cost effectively to overcome the difficulties associated with previous designs. As discussed in detail below, the secondary inductive element 1240 can also be operated at a lower frequency, such as at about 2 MHZ, allowing the secondary inductive element 1240 to be very compact and to fit in a limited space on top of the dielectric window 1210.

According to exemplary aspects of the present disclosure, the primary inductive element 1230 and the secondary inductive element 1240 are operated at different frequencies. The frequencies are sufficiently different to reduce cross-talk between the primary inductive element 1230 and the secondary inductive element 1240. For instance, the frequency applied to the primary inductive element 1230 can be at least about 12.5 times greater than the frequency applied to the secondary inductive element 1240.

The plasma processing apparatus 1100 may include one or more components with a coating, such as an electroplated coating (e.g., an anodized electroplated coating) or a PVD defined coating. For instance, one or more of the workpiece support contained within the processing chamber 1120, the gas injection insert 1140, or other component may include a coating according to aspects of the present disclosure.

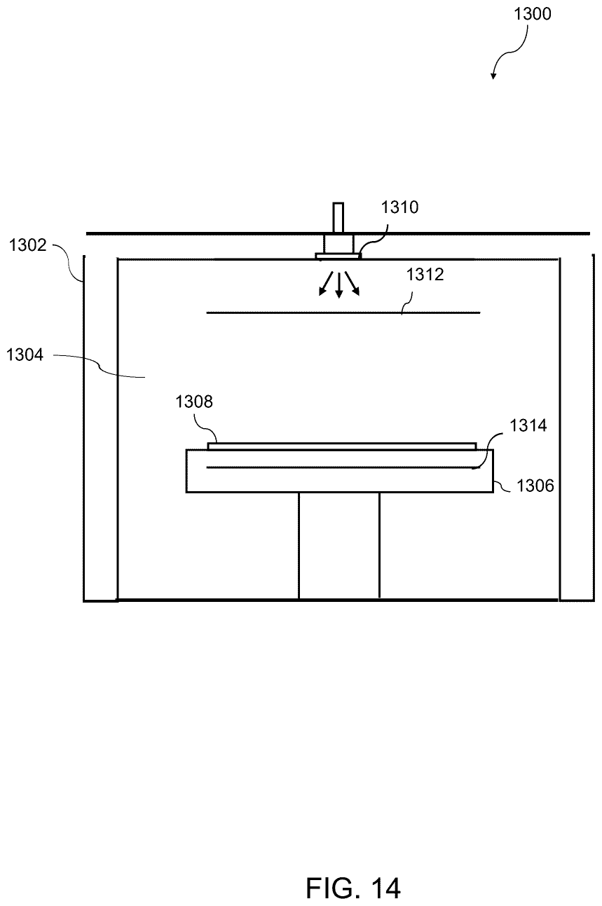

FIG. 14 depicts an example plasma processing system 1300 according to example embodiments of the present disclosure. The example plasma processing system 1300 includes a chamber wall 1302 that defines an interior portion 1304 of the plasma processing system 1300. The plasma processing system 1300 includes a workpiece support 1306 on which a workpiece 1308, such as a semiconductor wafer, may be processed. The plasma processing system 1300 includes a showerhead 1310 to feed process gas into the interior portion 1304 of the plasma processing system 1300. The plasma processing system 1300 includes a first electrode 1312 and a second electrode 1314. The first electrode 1312 and/or the second electrode 1314 may be biased to provide a capacitively coupled plasma source in the interior portion 1304. It will be understood by one skilled in the art, using the disclosures provided herein, that any number of subcomponents may be used to provide electrical potential to the first electrode 1312 and/or the second electrode 1314 to generate the capacitively coupled plasma.

The plasma processing system 1300 may include one or more components with a coating, such as an electroplated coating (e.g., an anodized electroplated coating) or a PVD defined coating. For instance, one or more of the chamber walls 1302, the workpiece support 1306, the showerhead 1310, the first electrode 1312, the second electrode 1314, or other component may include a coating according to aspects of the present disclosure.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A plasma processing system, comprising:
a plasma chamber;
an inductive coil disposed about the plasma chamber;
a processing chamber downstream of the plasma chamber;
a workpiece support in the processing chamber; and
a component with a coating in the processing chamber, the plasma chamber, or between the processing chamber and the plasma chamber.

2. The plasma processing system of claim 1, wherein the component with the coating is at least a part of a separation grid separating the plasma chamber from the processing chamber.

3. The plasma processing system of claim 1, wherein the component with the coating is at least a part of a thermal structure, wherein the thermal structure is configured to at least partially heat or cool a workpiece.

4. The plasma processing system of claim 1, wherein the component comprises copper and the coating is configured to reduce interaction between a plasma and the copper of the component.

5. The plasma processing system of claim 1, wherein the component is configured to present a chemically uniform surface to a plasma.

6. The plasma processing system of claim 1, wherein the coating has a surface reactivity to a process plasma that is lower than a surface reactivity of an underly material of the component.

7. The plasma processing system of claim 1, wherein the component with the coating is at least a part of a showerhead.

8. The plasma processing system of claim 1, wherein the component with the coating is at least a part of a gas injection insert.

9. The plasma processing system of claim 1, wherein the component with the coating is at least a part of a Faraday shield, a confinement ring, or a chamber wall in the plasma chamber, the processing chamber, or another chamber of the plasma processing system.

10. The plasma processing system of claim 1, further comprising a first electrode and a second electrode, wherein at least one of the first electrode or the second electrode are biased to provide a capacitively coupled plasma source, wherein the component with the coating comprises at least one of the first electrode or the second electrode.

11. The plasma processing system of claim 1, wherein the component comprises an alloy.

12. The plasma processing system of claim 8, wherein the coating is a material that is the same as a bulk material of the alloy.

13. The plasma processing system of claim 1, wherein the coating comprises a material that differs from a bulk material of the component.

14. The plasma processing system of claim 1, wherein the coating comprises an aluminum coating.

15. The plasma processing system of claim 11, wherein the aluminum coating comprises a purity in a range of about 90% to about 99.99%.

16. The plasma processing system of claim 11, wherein the aluminum coating comprises a thickness that is in a range of about 2 microns to about 400 microns.

17. The plasma processing system of claim 1, wherein the coating is an anodized coating.

18. The plasma processing system of claim 14, wherein the anodized coating comprises an oxide layer having a thickness of about 2 micrometers to about 200 micrometers.

19. A method for providing a coating to a component for use in a plasma processing system, comprising:
implementing a deposition process to a component of a plasma processing system to provide a coating on a surface of the component.

20-28. (canceled)

29. A plasma processing system, comprising:
a plasma chamber;
an inductive coil disposed about the plasma chamber;
a processing chamber downstream of the plasma chamber;
a workpiece support in the processing chamber;
a thermal structure; and
a coating disposed on the thermal structure.

30.-47 (canceled)
